(19) United States
(12) Patent Application Publication
(10) Pub. No.: US 2024/0213384 A1
(43) Pub. Date: Jun. 27, 2024

(54) N-TYPE SEMICONDUCTOR LAYER, SOLAR CELL, MULTI-JUNCTION SOLAR CELL, SOLAR CELL MODULE, AND PHOTOVOLTAIC POWER GENERATION SYSTEM

(71) Applicant: KABUSHIKI KAISHA TOSHIBA, Tokyo (JP)

(72) Inventors: Yasutaka Nishida, Tama Tokyo (JP); Naoyuki Nakagawa, Setagaya Tokyo (JP); Soichiro Shibasaki, Nerima Tokyo (JP); Yuya Honishi, Saitama Saitama (JP); Yukitami Mizuno, Ota Tokyo (JP); Mutsuki Yamazaki, Yokohama Kanagawa (JP); Atsushi Wada, Kawasaki Kanagawa (JP); Sara Yoshio, Yokohama Kanagawa (JP); Kazushige Yamamoto, Yokohama Kanagawa (JP)

(21) Appl. No.: 18/599,293

(22) Filed: Mar. 8, 2024

Related U.S. Application Data
(63) Continuation of application No. PCT/JP2023/011028, filed on Mar. 20, 2023.

(30) Foreign Application Priority Data
Sep. 20, 2022 (JP) 2022-149608

(51) Int. Cl. H01L 31/032; H01L 31/0725

(52) U.S. Cl. CPC H01L 31/0321; H01L 31/0725

(57) ABSTRACT

Embodiments described herein relate generally to a n-type layer, a solar cell, a multi-junction solar cell, a solar cell module, and a photovoltaic power generation system. An n-type layer according to an embodiment includes amorphous gallium oxide as a main component. A conductive type of the n-type layer is n-type. One or more lanthanoid series elements whose amount is more than 0 [atom %] and 67 [atom %] or less of Ga contained in the amorphous gallium oxide are doped at Ga (II) site of the amorphous gallium oxide.

### CROSS-REFERENCE TO RELATED APPLICATIONS

This application is a Continuation application of PCT International Patent Application No. PCT/JP2023/011028, the International Filing Date of which is Mar. 20, 2023, which is based upon and claims the benefit of priority from Japanese Application 2022-149608, the filling Date of which is Sep. 20, 2022, the entire contents of both of which are incorporated herein by reference.

### FIELD

Embodiments described herein relate generally to an n-type layer, a solar cell, a multi-junction solar cell, a solar cell module, and a photovoltaic power generation system.

### BACKGROUND

Cu₂O solar cells are characterized by using Cu₂O having high transmittance as a p-type light-absorbing layer. It is important that compatibility between a n-type layer connecting to the Cu₂O layer and the Cu₂O layer to obtain the high transmittance and excellent Voc. In view of the offset of conduction band, Ga₂O₃ is preferable and carrier doping of the n-type layer is important for further improving the performance of solar cells. A carrier source of current known β-Ga₂O₃(beta-Ga₂O₃) is not fully understood and suggested endogenous or exogenous hydrogen impurity from the reports.

Two mechanisms of the carrier source which is endogenous hydrogen are listed as follows.
1. Interstitial hydrogen captured by oxygen atom (weakly bonded as —OH in the interstice) (ref: Non-patent Literature 1)
2. Defect complexes of deep acceptor level by Ga vacancy (ref: Non-patent Literature 2)

In particular, it has been reported that the latter can be tuned from the acceptor to the donor by how many hydrogens are trapped around the Ga defect (ref: Non-patent Literature 3). Therefore, it can be assumed that the control of Ga defects via thermal processing, as well as the control of intrinsic hydrogen atoms and exogenous hydrogen exposure, is important for carrier generation of β-Ga₂O₃(beta-Ga₂O₃). In addition, the migration mechanism caused by the oxygen defect (ref: Non-patent Literature 4), which was discussed in the past, is considered to be almost rejected at present. As for the carrier sources other than hydrogen, with the exception of Si and F, the effect on the electronic state of the bulk itself is indirect, and there is almost no effect of precursor induced atoms.

In addition, it is traditionally known that atoms adjacent to the periodic table of the target atom is introduced as a dopant for the carrier doping of semiconductors. It is known that the carrier dopant for Ga atom of ideal crystal structure of β-Ga₂O₃(beta-Ga₂O₃) is Si and Sn by the first-principles calculations. The carrier doping replacing Ga of Ga (I) site of β-Ga₂O₃(beta-Ga₂O₃) with Si and the carrier doping replacing Ga of Ga (I) site of β-Ga₂O₃(beta-Ga₂O₃) with Sn are known. Both Si at Ga (I) site and Sn at Ga (II) site are n-type dopant for β-Ga₂O₃(beta-Ga₂O₃).

Otherwise, there have been few reports of the carrier doping for amorphous Ga₂O₃(a-Ga₂O₃) formed by low temperature deposition process that Sn is doped (ref: Non-patent Literature 4), even though there have been many reports of β-Ga₂O₃(beta-Ga₂O₃). In the low temperature deposition process such as sputtering, a-Ga₂O₃ formed rather than β-Ga₂O₃(beta-Ga₂O₃). Therefore, when such low temperature process is applied the knowledge about β-Ga₂O₃(beta-Ga₂O₃) cannot be adopted to a-Ga₂O₃. When a-Ga₂O₃ is used as a n-type layer which is in contact with Cu₂O layer or the like, further knowledge about new dopants for a-Ga₂O₃ is required.

The amorphous lanthanoid gallium oxide used as an insulating film of a semiconductor device was reported (ref: Non-patent Literature 1). a-Ga₂O₃ was reported as an insulating film but not reported as n-type layer applicable to solar cell.

### BRIEF DESCRIPTION OF THE DRAWINGS

FIG. 1 is a schematic cross-sectional diagram of a n-type layer according to an embodiment.

FIG. 2 is a summary of procedures of a density functional theory method.

FIG. 3 is a diagram of a crystal structure of ideal Ga₂O₃.

FIG. 4 is a radial distribution function (RDF) of ideal Ga₂O₃.

FIG. 5 is a radial distribution function (RDF) of ideal Ga₂O₃.

FIG. 6 is a radial distribution function (RDF) of ideal Ga₂O₃.

FIG. 7 is a diagram of local structure of ideal Ga₂O₃.

FIG. 8 is a diagram of a charge density distribution of ideal Ga₂O₃.

FIG. 9 is a diagram of an example of a thermal profile of a melt and quench method (MQ method)

FIG. 10 is a diagram of a crystal structure of amorphous Ga₂O₃ obtained by a melt and quench method.

FIG. 11 is a radial distribution function of amorphous Ga₂O₃ obtained by a melt and quench method.

FIG. 12 is a diagram of amorphous Ga₂O₃ doped with a lanthanoid series element.

FIG. 13 is a diagram of density of states of amorphous Ga₂O₃ doped with a lanthanoid series element or Zr.

FIG. 14 is a diagram of an order of stable dopant for amorphous Ga₂O₃ doped with a lanthanoid series element.

FIG. 15 is a schematic cross-sectional diagram of a solar cell according to an embodiment.

FIG. 16 is a schematic cross-sectional diagram of a multi-junction solar cell according to an embodiment.

FIG. 17 is a schematic perspective diagram of a solar cell module according to an embodiment.

FIG. 18 is a schematic cross-sectional diagram of a solar cell module according to an embodiment.

FIG. 19 is structural diagram of a photovoltaic power generation system according to an embodiment.

FIG. 20 is a schematic diagram of a vehicle.

FIG. 21 is a schematic diagram of a flying object.

### DETAILED DESCRIPTION

An n-type layer according to an embodiment includes amorphous gallium oxide as a main component. A conductive type of the n-type layer is n-type. One or more lanthanoid series elements whose amount is more than 0 [atom %] and 67 [atom %] or less of Ga contained in the amorphous gallium oxide are doped at Ga (II) site of the amorphous gallium oxide.

Hereinafter, an embodiment will be described in detail with reference to the drawings. Unless otherwise specified, values at 25° C. and 1 atm (atmosphere) are illustrated. An average represents an arithmetic mean value. Each concentration represents an average concentration of a region or a layer. When a specified element is detected by, for example, SIMS (Secondary Ion Mass Spectrometry), it is treated as the specified element is included. When a specified element is not detected by, for example, SIMS it is treated as the specified element is not included.

### First Embodiment

A first embodiment relates to an n-type semiconductor layer 100. FIG. 1 illustrates a schematic cross-sectional diagram of a n-type layer according to an embodiment. The n-type layer 100 contains amorphous gallium oxide. It is preferable that the n-type layer 100 contains one or more lanthanoid series elements as a dopant for Ga. A preferable constituent is developed relating to the amorphous gallium oxide from simulations. Hereinafter, simulations according to the first embodiment will be described.

### (First-Principles Calculation)

Recently, by virtue of developing the simulation method of first-principles calculation, electronic states in materials can be predicted precisely. The first-principles calculation based on first-principles density functional theory is popular for solid system, for example inorganic materials. A pseudopotential method for calculations of total energy (Reference Documents; I. Morrion, D. M. Bylander, and L. Kleinman, Phys. Rev. B 47, 6728 (1993)) T. Ozaki and H. Kino, Phys. Rev. B 72 045121 (2005) (LCPAO method))) is used. A summary of calculating procedures of a density functional theory method is shown in FIG. 2.

φᵢ in the procedure 1 and procedure 2 is Kohn-Sham orbital. H_{KS} in the procedure 1 is Kohn-Sham Hamiltonian. The left side of formula in the procedure 2 is electron density distribution. V_{Hartree} in the procedure 3 and the procedure 4 is Hartree potential. δE_{xc} in the procedure 4 is exchange-correlation energy. The self-consistent conditions are effective potential which is updated from input effective potential being calculated in the procedure 3 and matching within a certain margin of error. First, Kohn-Sham Hamiltonian is constructed by input arbitrary effective potential, the eigenvalue problem is solved in the procedure 1, and electron density distribution is obtained. Next, input electron density distribution and the electron density distribution obtained in the procedure 2 are mixed, Poisson formula is solved. Then, effective potential is obtained in the procedure 4 and Khon-Sham Hamiltonian is updated in the procedure 5. These procedures are repeated until the difference between input electron density distribution and the electron density distribution obtained in procedure 2 converge within a certain margin of error. This repeated calculation is self-consistent calculation (SCF calculation). The electron density distribution obtained by converging the SCF calculation matches the electron density distribution in ground state, and various physical quantities can be calculated using this electron density distribution.

(First-Principles Calculation of Ga₂O₃)

Hereinafter, for the disclosed technology, the Ga₂O₃ simulation result using first-principles calculation based on the density functional theory will be described briefly. It is known that the crystal structure of Ga₂O₃ is crystal polymorphism including 5 types: α (alfa) [symbol] β (beta) [symbol] γ (gamma) [symbol] δ (delta), and ε (epsilon). The most stable structure in air at normal temperature is β-Ga₂O₃ (beta-Ga₂O₃). The others are metastable crystals. In the present calculation of amorphous Ga₂O₃, an initial stable structure is set to β-Ga₂O₃(beta-Ga₂O₃), an amorphous structure is created based on the structure, and calculation of doping is executed. Hereinafter, calculation conditions for the present simulation and its validity will be described.

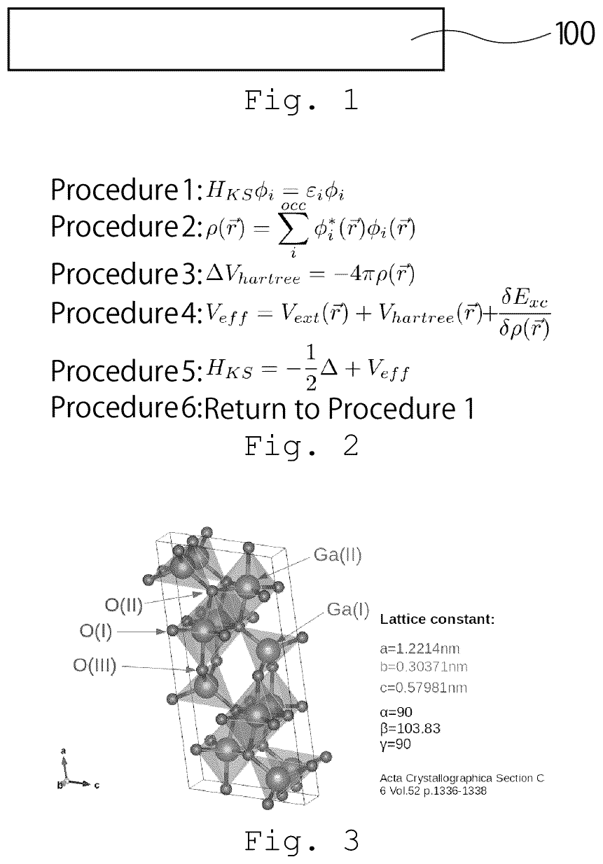

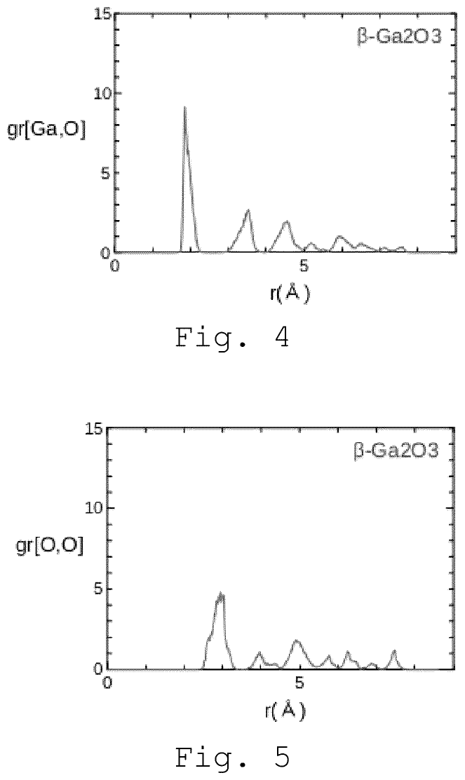

A diagram of a crystal structure of ideal β-Ga₂O₃ (beta-Ga₂O₃) is shown in FIG. 3 (FIG. 3 is created on the basis of the contents of NPL 6 (J. Åhman, et, al, Acta Cryst. C52, 1336-1338 (1996)).). β-Ga₂O₃ (beta-Ga₂O₃) contains two Ga atom sites which are not equivalent and three O (oxygen) atom sites which are not equivalent. The characteristics of the crystal structure are that four oxygen atoms are coordinated to Ga (I) site and six oxygen atoms are coordinated to Ga (I) site. Additionally, Ga atoms are three-coordinated to around O(I) site, Ga atoms are four-coordinated to O(II) site, and Ga atoms are coordinated to O (III) site.

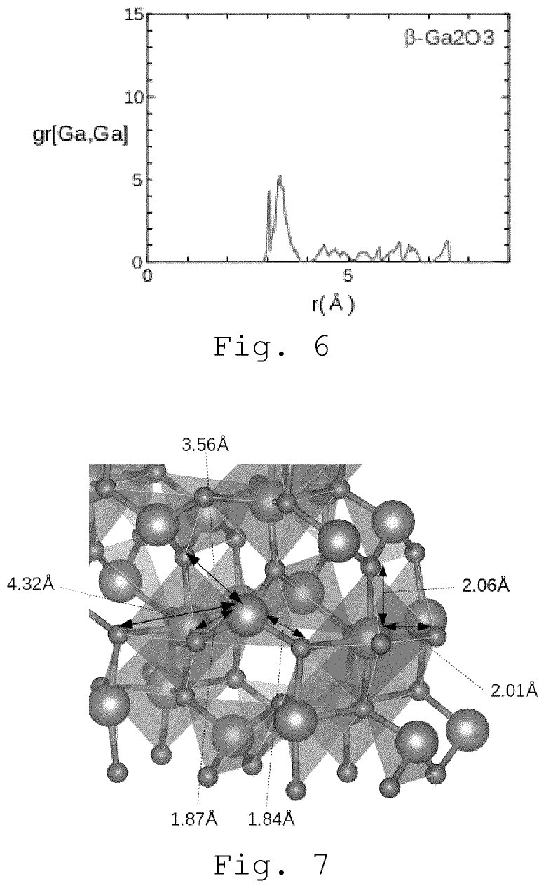

Radial distribution functions (RDFs) of ideal crystal structure are shown in FIG. 4, FIG. 5, and FIG. 6. RDFs of FIG. 4, FIG. 5, and FIG. 6 are obtained from calculations by averaging structures of a total of 50 steps which are obtained by calculating structural relaxation (NVT calculation) of first-principles calculation at 300 [K]. Even though it is perfect crystal, each peak has width since fluctuation of atom potion is occur due to the thermal energy of the external field at 300 [K]

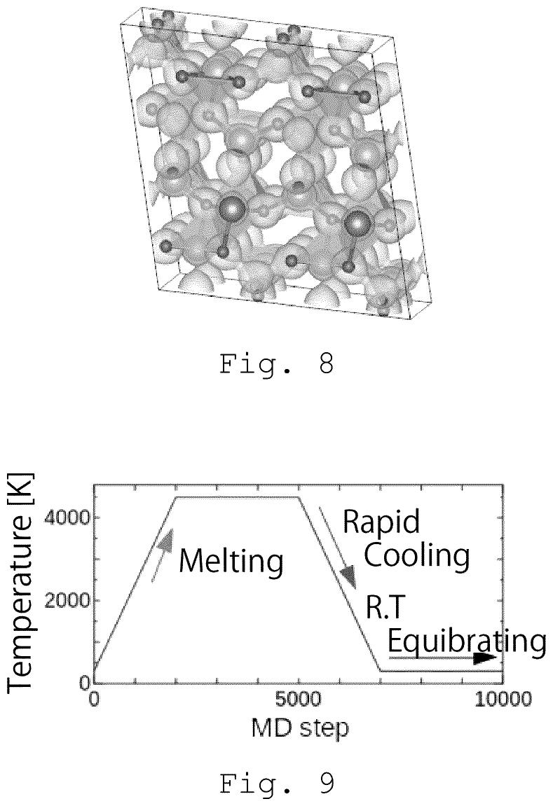

The RDF of gr[Ga, O] shown in FIG. 4 shows distribution of O (oxygen) atoms with respect to distance of Ga-O centered at Ga. Focusing on the gr[Ga, O], a large peak (first peak) is observed at around r=2 [angstrom] and a second peak at around r=3.5 [angstrom] and a third peak at around r=4.5 [angstrom] are observed. This represents coordination of O (oxygen) atom centered at Ga site in the crystal structure. These are corresponding to that the distance between the nearest O (oxygen) atoms around the Ga(I) site is 1.84 [angstrom] and the distance between the nearest O (oxygen) atoms around the Ga (II) site is 2.06 [angstrom]. Additionally, the crystal structure teaches that the distance between the Ga (I) site and the second nearest oxygen atom is 3.56 [angstrom] and the distance between the Ga (I) site and the third nearest oxygen atom is 4.32 [angstrom]. Each of these distance is corresponding to the second peak and the third peak observed in RDF of gr[Ga, O]. Similarly, the RDF of gr[Ga, O] shown in FIG. 5 shows that a distinctive large peak presents at around 3 [angstrom]. Similarly, the RDF of gr[Ga, O] shown in FIG. 6 shows that a distinctive large peak presents at around 4 [angstrom]. A diagram of local structure of ideal Ga₂O₃ is shown in FIG. 7. In the diagram of local structure, interatomic distances of ideal β-Ga₂O₃ (beta-Ga₂O₃) are shown.

A diagram of a charge density distribution of ideal Ga₂O₃ obtained by NVT calculation at 300 [K] is shown in FIG. 8. FIG. 8 teaches that the electron density between Ga-O is distributed in a network-like manner and covalent bonding such as Si crystal is expected. Additionally, it is estimated that the band gap of β-Ga₂O₃ (beta-Ga₂O₃) is E_{g}=2.28 [eV] from the results of calculation of state density based on GGA-PBE used in the present calculations.

(First-Principles Calculation for Producing Amorphous Ga₂O₃ Structure)

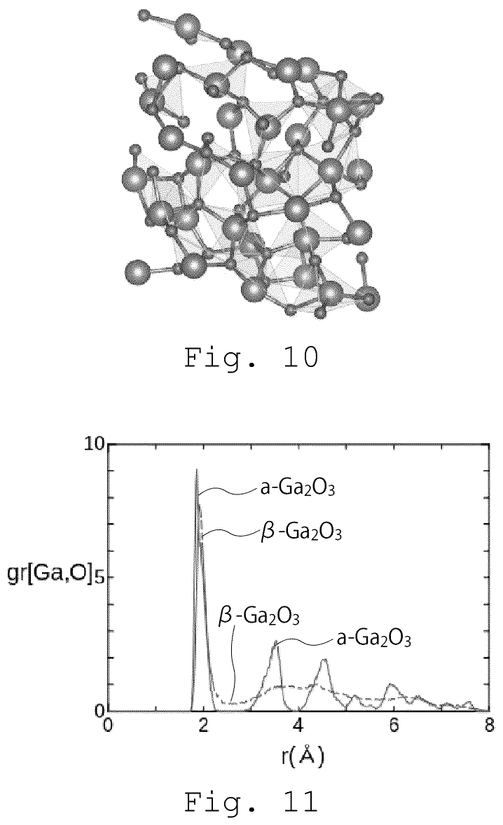

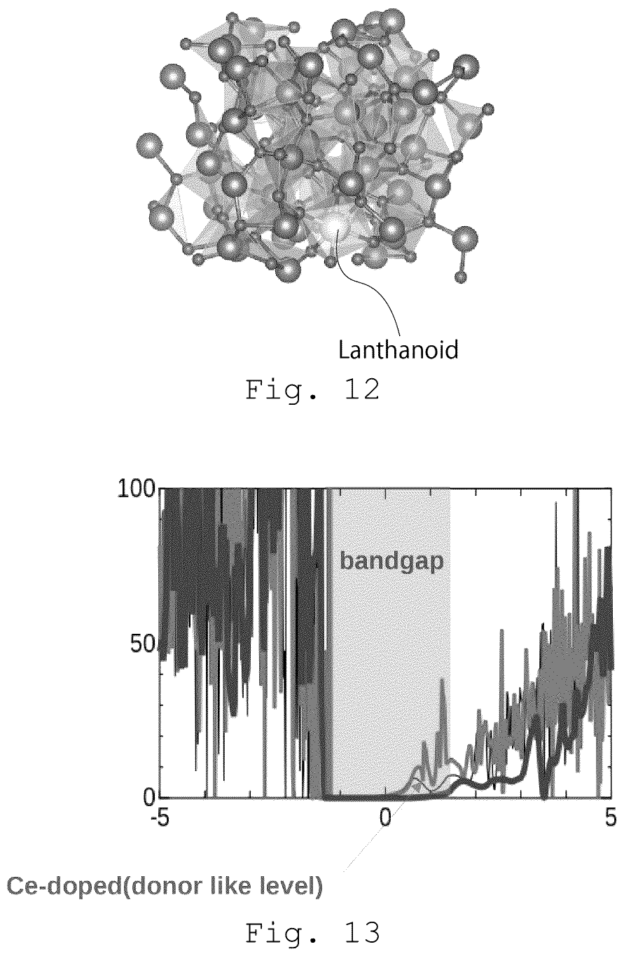

Melt and Quench method (MQ method) is used for producing the structure of amorphous Ga₂O₃(a-Ga₂O₃). The MQ method is a method to produce amorphous structure by the firs-principles calculation. Crystal of β-Ga₂O₃ (beta-Ga₂O₃) is melted using Molecular Dynamics (MD) simulations and it is cooled rapidly after a certain MD steps. A thermal profile used in the present simulation is shown in FIG. 9. The temperature is increased from 300 [K] (room temperature) to 4500 [K], a certain MD steps are repeated, and equilibrating is done by rapid cooling to 300 [K]. A diagram of a crystal structure of amorphous Ga₂O₃ obtained by a melt and quench method is shown in FIG. 10. Confirming the validity of the amorphous structure, result of comparing the ideal crystal structure and RDF (a radial distribution function of amorphous Ga₂O₃ obtained by a melt and quench method) is shown in FIG. 11. In the RDF of gr[Ga, O] of the ideal crystal, several distinctive peaks corresponding to the interatomic distances. In the RDF of gr[Ga, O] of a-Ga₂O₃, main peak (the first peak) is observed. In the RDF of gr[Ga, O] of a-Ga₂O₃, the second peak and the third peak is not observed. The RDF of gr[Ga, O] of a-Ga₂O₃ depicts accurately the characteristics of the amorphous structure that short-distance order is maintained but long-distance order is not maintained.

Based on the findings of the structure of amorphous Ga₂O₃ obtained by MQ method, transition metals and lanthanoid series elements are focused as candidates for dopant of n-type material to the amorphous Ga₂O₃ (a-Ga₂O₃), and the first-principles calculation is performed for a system in which Ga element is (partially) replaced by Si [symbol] V [symbol] Y [symbol] Zr [symbol] Nb [symbol] Sn [symbol] Ce [symbol] Hf [symbol] Ta, or Ti. For the selection of replacement site, the amorphous structure of Ga₂O₃ structure obtained by MQ method, it was discovered that a lot of Ga (II) site having hexahedral oxygen coordination are remained. It was discovered that up to 40% of Ga site in the amorphous gallium oxide is Ga (II) site. Therefore, this discovery teaches an element which is stably replacing Ga (II) site of the amorphous Ga₂O₃ may works as a dopant. Calculating stabilization energies of each element, the order “Ce>Sn>Y>Hf>Zr>Ta>Nb>Si>Ti>V” is obtained.

When 40% of Ga site of amorphous gallium oxide is Ga (II) site and all of Ga (II) site is replaced with one or more lanthanoid series elements (L), amorphous (Ga_{0.6}L_{0.4})₂O₃ is obtained. Then, L whose amount is 67 [atom %] of Ga is contained in the amorphous (Ga_{0.6}L_{0.4})₂O₃. From the above calculations, it was discovered that the n-type semiconductor layer 100 which contains amorphous gallium oxide as a main component, whose conductive type is n-type, and in which one or more lanthanoid series elements whose amount is more than 0 [atom %] and 67 [atom %] or less of Ga contained in the amorphous gallium oxide are doped at Ga (II) site of the amorphous gallium oxide, has high carrier concentration and is preferable for n-type layer which is provided on a p-type layer, for example, Cu₂O layer. In the same viewpoint, it is preferable that one or more lanthanoid series elements whose amount is more than 10 [atom %] and 40 [atom %] or less of Ga contained in the amorphous gallium oxide are doped at Ga (II) site of the amorphous gallium oxide.

It is preferable that 90 [wt %] or more and 100 [wt %] or less of the n-type semiconductor layer 100 is the amorphous gallium oxide (lanthanoid doped amorphous gallium oxide). It is more preferable that 95 [wt %] or more and 100 [wt %] or less of the n-type semiconductor layer 100 is the amorphous gallium oxide (lanthanoid doped amorphous gallium oxide). It is still more preferable that 98 [wt %] or more and 100 [wt %] or less of the n-type semiconductor layer 100 is the amorphous gallium oxide (lanthanoid doped amorphous gallium oxide). It is still more preferable the n-type semiconductor layer 100 consists of the amorphous gallium oxide (lanthanoid doped amorphous gallium oxide) (100 [wt %] of the n-type semiconductor layer 100 is the amorphous gallium oxide (lanthanoid doped amorphous gallium oxide)).

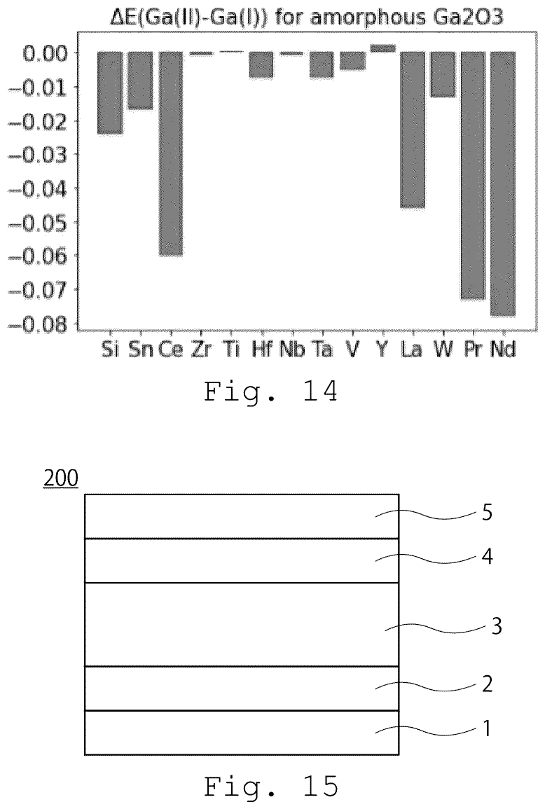

It is investigated whether the results would change with or without defects charge of anti-site defects replaced with above atoms, and a result that the Ga (II) site is stably replaced with above atoms with or without the charge is obtained. FIG. 12 shows a diagram of amorphous Ga₂O₃ doped with a lanthanoid series element. Additionally, the density of states is calculated limited to Ce and Zr to investigate early the doping effects, and a donor level-like state is found near the conduction band minimum of Ce as shown in FIG. 13, and it was found that Ce works dopant from the result. Furthermore, the density of states is calculated limited to the lanthanoid series elements, and the order shown in FIG. 14 is obtained. The result teaches La, Pr, and Nd other than Ce have high stability. Above result represents that using the lanthanoid series element as a dopant is prefer to the reported case such as a-Ga₂O₃ doped with Sn (non-patent literature 5)

It was discovered that one or more selected from the group consisting of Ce, La, Pr, and Nd is preferable for the lanthanoid series element(s) which is doped at Ga (II) site of amorphous gallium oxide. One or more selected from the group consisting of Ce, La, Pr, and Nd is preferable as the lanthanoid series element(s) which is doped at Ga (II) site of amorphous gallium oxide.

Ce is preferable as the lanthanoid series element(s) which is doped at Ga (II) site of amorphous gallium oxide.

La is preferable as the lanthanoid series element(s) which is doped at Ga (II) site of amorphous gallium oxide.

Pr is preferable as the lanthanoid series element(s) which is doped at Ga (II) site of amorphous gallium oxide.

Nd is preferable as the lanthanoid series element(s) which is doped at Ga (II) site of amorphous gallium oxide.

The total of Ga contained in the amorphous gallium oxide contained in the n-type semiconductor layer 100 and the dopant of the lanthanoid series element(s) (the one or more lanthanoid series elements contained in the amorphous gallium oxide as a dopant) is preferably 95 [wt %] or more and 100 [wt %] or less of total elements excluding oxygen contained in the amorphous gallium oxide, is more preferably 98 [wt %] or more and 100 [wt %] or less of elements excluding oxygen contained in the amorphous gallium oxide, and still more preferably 99 [wt %] or more and 100 [wt %] or less of elements excluding oxygen contained in the amorphous gallium oxide. It is preferable that the total of Ga contained in the amorphous gallium oxide contained in the n-type semiconductor layer 100 and the dopant of the lanthanoid series element(s) is preferably 100 [wt %] of total elements excluding oxygen contained in the amorphous gallium oxide.

The above results are discussed below. β-Ga₂O₃ (beta-Ga₂O₃) is originally n-type, and Si and/or Sn is easily doped at Ga(II) site. The carrier concentration of β-Ga₂O₃ (beta-Ga₂O₃) increases by Si and/or Sn doping. When a-Ga₂O₃ is formed ordinally ALD method or sputtering, the formed a-Ga₂O₃ easily becomes insulation, and the formed a-Ga₂O₃ which is doped with Si and/or Sn is also supposed to be insulation. Considering the above simulation results and disclosed contents shown in FIG. 7 of non-patent literature and the like, it is considered that Ga₂O₃ which is referred to as amorphous does not have ideal a-Ga₂O₃ (amorphous) and the dopant replaces Ga (II) site other than Ga (II) site.

Comparing forming by ordinary ALD method or sputtering and MQ method and focusing on the interatomic distance, the insulating amorphous gallium oxide formed by ordinary ALD or sputtering is considered to be incomplete amorphous having β type (beta-type) characteristics. When the ideal a-Ga₂O₃ is used, the n-type a-Ga₂O₃ whose Ga (II) site is replaced with the lanthanoid series element(s) is obtained. When the a-Ga₂O₃ having β type (beta-type) characteristics is used, the insulating a-Ga₂O₃ would be obtained since Sn and/or Sb may be doped at Ga site, for example, Ga (I) site or the like other than Ga (II) site. Since the amount of the Ga (II) site in the incomplete amorphous Ga₂O₃ cannot be estimated, it is difficult to obtain experimentally a n-type layer of a-Ga₂O₃ (incomplete amorphous Ga₂O₃) whose carrier concentration is high.

When the Ga (I) site or the like other than Ga (II) site is replaced with the dopant, it may close to insulating type without increasing carrier concentration. Therefore, it is preferable that 90 [atom %] or more and 100 [atom %] or less of the one or more lanthanoid series elements contained in the n-type semiconductor layer 100 is doped at Ga (II) site.

### Second Embodiment

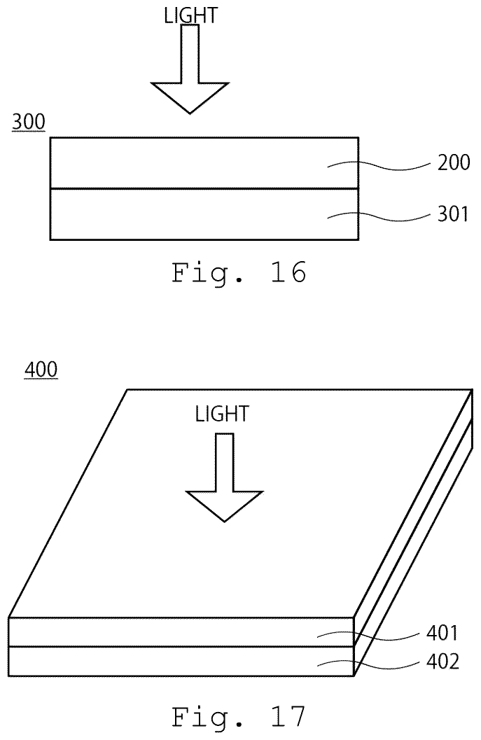

A second embodiment relates to a solar cell. A cross-sectional view of the solar cell according to the second embodiment is illustrated in FIG. 15. As Illustrated in FIG. 15, the solar cell 200 according to present embodiment includes a substrate 1, a p-electrode 2 as a first electrode, a p-type light-absorbing layer 3, an n-type layer 4, and an n-electrode 5 as a second electrode. An intermediate layer which is not illustrated may be included between, for example, the n-type layer 4 and the n-electrode 5. Sunlight may be incident from either the n-electrode 5 side or the p-electrode 2 side, but is more preferably incident from the n-electrode 5 side. The n-type layer 4 includes the n-type semiconductor layer 100 according to the embodiment. Since the solar cell 200 according to the embodiment is a transmissive solar cell, it is preferable that the solar cell 200 is used as a top cell (light incident side) of a multi-junction solar cell. In FIG. 15, the substrate 1 is provided on a side of the p-electrode 2 opposite to the p-type light-absorbing layer 3 side. Hereinafter, the embodiment shown in FIG. 15 will be described that is similar to an embodiment whose substrate 1 is provided on the n-electrode 5 side. In the solar cell 200 of the embodiment, light is incident from the n-electrode 5 side toward the p-electrode 2 side.

The substrate 1 is a transparent substrate. A transparent organic substrates such as acrylic, polyimide, polycarbonate, polyethylene terephthalate (PET), polypropylene (PP), fluorine-based resins (polytetrafluoroethylene (PTFE), perfluoroethylene propene copolymer (FEP), ethylene tetrafluoroethylene copolymer (ETFE), polychlorotrifluoroethylene (PCTFE), perfluoroalkoxy alkane (PFA), and the like), polyarylate, polysulfone, polyethersulfone, and polyetherimide, and inorganic substrates such as soda lime glass, white glass, chemically strengthened glass, and quartz can be used as the substrate 1. As the substrate 1, the substrates listed above can be stacked.

The p-electrode 2 is provided on the substrate 1 and is disposed between the substrate 1 and the p-type light-absorbing layer 3. The p-electrode 2 preferably forms an ohmic contact with the p-type-light absorbing layer 3. The p-electrode 2 is a conductive layer having transparency provided on the p-type light-absorbing layer 3 side. A thickness of the p-electrode 2 is typically 100 nm or more and 2,000 nm or less. In FIG. 15, the p-electrode 2 is in direct contact with the light-absorbing layer 3. It is preferable that the p-electrode 2 includes one or more layers of transparent conductive oxide films. The transparent conductive oxide film is not particularly limited, and is an indium tin oxide (ITO), an Al-doped zinc oxide (AZO), a boron-doped zinc oxide (BZO), a gallium-doped zinc Oxide (GZO), a doped tin oxide, a titanium-doped indium oxide (ITiO), an indium zinc oxide (IZO), an indium gallium zinc oxide (IGZO), a hydrogen-doped indium oxide (IOH), or the like. The transparent conductive oxide film may be a stacked film having a plurality of films. A dopant for a film of tin oxide or the like is not particularly limited as long as the dopant is one or more elements selected from the group consisting of In, Si, Ge, Ti, Cu, Sb, Nb, Ta, W, Mo, F, Cl, and the like. It is preferable that the p-electrode 2 preferably includes a tin oxide film doped with one or more elements selected from the group consisting of In, Si, Ge, Ti, Cu, Sb, Nb, Ta, W, Mo, F, Cl, and the like. In the doped tin oxide film, one or more elements selected from the group consisting of In, Si, Ge, Ti, Cu, Sb, Nb, Ta, W, Mo, F, Cl, and the like are preferably contained at 10 atom % or less with respect to tin contained in the tin oxide film. As the p-electrode 2, a stacked film in which a transparent conductive oxide film and a metal film are stacked can be used. The metal film preferably has a thickness of 1×10⁻⁹ [m] or more and 2×10⁻⁶ [m] or less, and the metal (including alloy) contained in the metal film is not particularly limited to Mo, Au, Cu, Ag, Al, Ta, W, or the like. It is preferable that the p-electrode 2 includes a dot-shaped, line-shaped, or mesh-shaped electrode (one or more selected from the group consisting of metal, an alloy, graphene, a conductive nitride, and a conductive oxide) between the transparent conductive oxide film and the substrate 1 or between the transparent conductive oxide film and the p-type light-absorbing layer 3. It is preferable that the dot-shaped meatal, the line-shaped metal, or the mesh-shaped metal has an aperture ratio of 50% or more with respect to the transparent conductive film. The dot-shape metal, the line-shape metal, or the mesh-like metal is not particularly limited, and is Mo, Au, Cu, Ag, Al, Ta, W, or the like. When the metal film is used for the p-electrode 2, it is preferable that a film thickness is about 5 [nm] or less from the viewpoint of transparency. When the line-shaped or mesh-shaped metal film is used, since the transparency is obtained owing to the opening, the film thickness of the metal film is not limited thereto.

It is preferable that a doped tin oxide film is provided on an outermost surface of the transparent conductive oxide film on the p-type light-absorbing layer 3 side. It is preferable that at least part of the doped tin oxide film provided on the outermost surface of the transparent conductive oxide film on the p-type light-absorbing layer 3 side is in direct contact with the p-type light-absorbing layer 3.

The p-type light-absorbing layer 3 is a p-type semiconductor layer. The p-type light-absorbing layer 3 is provided on the p-electrode 2. The p-type light-absorbing layer 3 may be in direct contact with the p-electrode 2, or other layers may be present as long as the electric contact with the p-electrode 2 can be secured. The p-type light-absorbing layer 3 is disposed between the electrode 2 and the n-type layer 4. The p-type light-absorbing layer 3 is in direct contact with the n-type layer 4. It is preferable that the compound semiconductor of the p-type light-absorbing layer 3 which is in non-doped state is also p-type. It is preferable that a semiconductor layer as the compound semiconductor which is p-type in non-doped state contains cuprous oxide (cuprous oxide compound).

When the p-type light-absorbing layer 3 contains the cuprous oxide, it is preferable that the p-type light-absorbing layer 3 contains the cuprous oxide compound as a main component. Therefore, the p-type light-absorbing layer 3 is a semiconductor containing the cuprous oxide compound. It is preferable that the p-type light-absorbing layer 3 is polycrystalline of the cuprous oxide compound. The cuprous oxide compound may contains a small amount of at least one selected from the group consisting of copper (Cu), cupric oxide (CuO), and copper hydroxide (Cu(OH)₂) as impurities.

When the amount of Cu atom is 1 in the cuprous oxide compound, it is preferable that the amount of oxygen atom in the cuprous oxide compound is 0.48 or more and 0.56 or less. When the amount of oxygen respect to the amount of cupper is large, the ratio of cupric oxide contained in the cuprous oxide compound increases. Then, it is not preferable that bandgap decreases and transmittance of the p-type light-absorbing layer 3 decreases. When the amount of oxygen respect to the amount of cupper is small, the ratio of cupper contained in the cuprous oxide compound increases. Then it is not preferable that transmittance of the p-type light-absorbing layer 3 decreases.

The cuprous oxide compound is an oxide containing cuprous oxide as a main component. When all metal elements contained in the p-type light-absorbing layer 3 is 100 [%]. cupper element contained in the p-type light-absorbing layer 3 is preferably 95 [%] or more and 100 [%] or less, more preferably 98 [%] or more and 100 [%] or less, and still more preferably 99 [%] or more and 100 [%] or less.

The cuprous oxide compound contains cupper and oxide, and optionally contains the element expressed by M1. The element expressed by M1 is at least one selected from the group consisting of Sn, Sb, Ag, Li, Na, K, Cs, Rb, Al, In, Zn, Mg, Ga, Si, Ge, N, P, B, Ti, Hf, Zr, Ca, Cl, F, Br, I, Mn, Tc, and Re.

It is preferable that 95 [wt %] or more and 100 [wt %] or less of the p-type light-absorbing layer 3 is the cuprous oxide compound. It is more preferable that 98 [wt %] or more and 100 [wt %] or less of the p-type light-absorbing layer 3 is the cuprous oxide compound. It is still more preferable that 99 [wt %] or more and 100 [wt %] or less of the p-type light-absorbing layer 3 is the cuprous oxide compound. 100 [wt %] of the p-type light-absorbing layer 3 consists of the cuprous oxide compound.

In view of the increasing short-circuit current density, the thickness of the p-type light-absorbing layer 3 is preferably 2000 [nm] or more and 15000 [nm] or less, preferably 4000 [nm] or more and 10000 [nm] or less, more preferably 4000 [nm] or more and 8000 [nm] or less, and still more preferably 4000 [nm] or more and 6000 [nm] or less.

The p-type light absorbing layer 3 is preferably deposited, for example, by sputtering or the like.

The n-type layer 4 is an n-type semiconductor layer. The n-type layer 4 is provided between the p-type light-absorbing layer 3 and the n-electrode 5. The n-type layer 4 is preferably provided on the p-type light-absorbing layer 3. The n-type layer 4 is in direct contact with a surface of the p-type light-absorbing layer 3 opposite to the surface which is in contact with the p-electrode 2. The n-type layer 4 which contains an oxide containing Ga as a base may further include other oxide. It is preferable that the n-type layer 4 includes a semiconductor layer containing an oxide containing Ga or a semiconductor layer containing an n-type cuprous oxide compound and an oxide containing Ga. The n-type layer 4 is one layer or stacked layers. It is preferable to use the n-type semiconductor layer 100 as a semiconductor layer containing an oxide containing Ga. When the n-type layer 4 is stacked layers, the n-type layer 4 preferably includes the n-type semiconductor layer 100 of the first embodiment and a semiconductor layer containing an oxide containing an element expressed by M2 and Ga.

It is preferable that the n-type layer 4 contains a compound (oxide) contains Ga as a main component. The n-type layer 4 may be a mixture of the oxide containing Ga as a main component and an oxide other than the oxide containing Ga as a main component, an oxide containing Ga as a main component doped with other element(s), or a mixture of an oxide containing Ga as a main component doped with other element(s) and an oxide other than the oxide containing Ga as a main component. The n-type layer 4 is one layer or stacked layers. 40 [atom %] or more of metal elements contained in the n-type layer 4 is preferably Ga. 50 [atom %] or more of metal elements contained in the n-type layer 4 is more preferably Ga. The metal elements contained in the n-type layer 4 is inclined from the p-type light-absorbing layer 3 side to the n-electrode 5 side.

The n-type layer 4 preferably contains an oxide containing the element expressed by M2 and Ga. The element expressed by M2 is at least one selected from the group consisting of H, Sn, Sb, Cu, Ag, Li, Na, K, Cs, Rb, Al, In, Zn, Mg, Si, Ge, N, B, Ti, Hf, Zr, and Ca. The n-type layer 4 may contain an oxide which does not contain Ga.

A film thickness of the n-type layer 4 is typically 3 [nm] or more and 100 [nm] or less. When the film thickness of the n-type layer 4 is less than 3 [nm], a leakage current is generated in a case where coverage of the n-type layer 4 is poor, and characteristics may be deteriorated. When the coverage is good, the film thickness is not limited to the above film thickness. When the film thickness of the n-type layer 4 exceeds 50 [nm], characteristics may be deteriorated due to an excessive increase in resistance of the n-type layer 4, or a short-circuit current may be reduced due to a decrease in transmittance. Accordingly, the film thickness of the n-type layer 4 is more preferably 3 [nm] or more and 20 [nm] or less and still more preferably 5 [nm] or more and 20 [nm] or less.

The n-electrode 5 is an electrode on the n-type layer 4 side having transparency to visible light. The n-electrode 5 is preferably provided on the n-type layer 4. The n-type layer 4 is sandwiched between the n-electrode 5 and the p-type light-absorbing layer 3. An intermediate layer (not illustrated) can be provided between the n-type layer 4 and the n-electrode 5. It is preferable that a transparent conductive oxide film is used for the n-electrode 5. It is preferable that the transparent conductive oxide film used for the n-electrode 5 is one or more kinds of semiconductor conductive films selected from the group consisting of an indium tin oxide, an aluminum-doped zinc oxide, a boron-doped zinc oxide, a gallium-doped zinc oxide, an indium-doped zinc oxide, a titanium-doped indium oxide, an indium gallium zinc oxide, and a hydrogen-doped indium oxide. A dopant for a film of tin oxide or the like is not particularly limited as long as the dopant is one or more elements selected from the group consisting of In, Si, Ge, Ti, Cu, Sb, Nb, Ta, W, Mo, F, Cl, and the like. The n-electrode 5 may include mesh-shaped or line-shaped electrode to reduce the resistance of the transparent conductive oxide film. The mesh-shaped or line-shaped electrode is not limited as long as Mo, Au, Cu, Ag, Al, Ta, or W. Graphene can be also used for the n-electrode 5. It is preferable that the graphene is stacked with Ag nano wires.

A thickness of the n-electrode 5 is obtained by cross-sectional observation with an electron microscope or a step profiler, and is not particularly limited, but is typically 50 nm or more and 2 μm or less.

The n-electrode 5 is preferably deposited, for example, by sputtering or the like.

### Third Embodiment

A third embodiment relates to a multi-junction solar cell. FIG. 16 illustrates a conceptual sectional diagram of a multi-junction solar cell according to the third embodiment. The multi-junction solar cell 300 of FIG. 16 includes the solar cell (first solar cell) 200 according to the second embodiment on the light incident side and a second solar cell 301. The band gap of the p-type light-absorbing layer of the second solar cell 301 is smaller than the band gap of the light-absorbing layer 3 of the solar cell 200 according to the second embodiment. Incidentally, the multi-junction solar cell according to the embodiment includes a solar cell in which three or more solar cells are jointed.

The band gap of the p-type light-absorbing layer 3 of the first solar cell 200 according to the second embodiment is about 2.0 eV-2.2 eV, and thus the band gap of the light-absorbing layer of the second solar cell 301 is preferably 1.0 eV or more and 1.6 eV or less. The light-absorbing layer of the second solar cell 301 is preferably selected from the group consisting of any one or more compound semiconductor layers among CIGS-based having a high In content and CdTe-based compound semiconductor layers, crystalline silicon and perovskite type compound.

### Fourth Embodiment

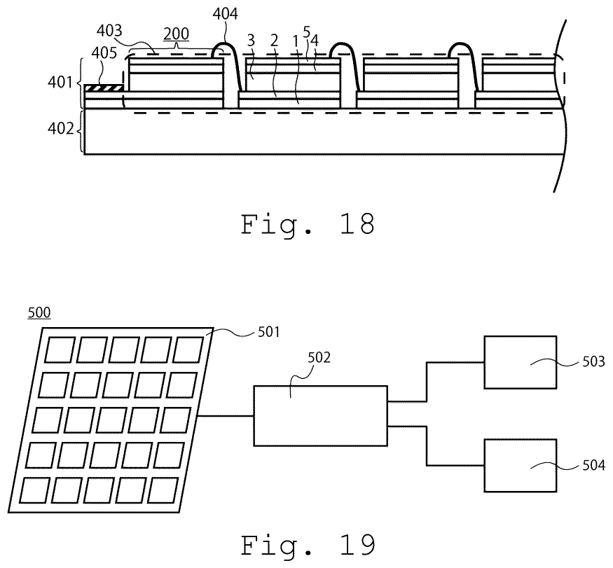

A fourth embodiment relates to a solar cell module. FIG. 17 illustrates a perspective diagram of a solar cell module 400 according to the fourth embodiment. The solar cell module 400 in FIG. 17 is a solar cell module in which a first solar cell module 401 and a second solar cell module 402 are stacked one on the other. The first solar cell module 401 is on the light incident side and includes the solar cell 200 according to the second embodiment. It is preferable to use the second solar cell 301 in the second solar cell module 402.

FIG. 18 illustrates a sectional diagram of the solar cell module 400. In FIG. 18, the structure of the first solar cell module 401 is illustrated in detail but the structure of the second solar cell module 402 is not illustrated. In the second solar cell module 402, the structure of the solar cell module is appropriately selected depending on the light-absorbing layer of the solar cell to be used. In the solar cell module 400 in FIG. 18, a plurality of submodules 403 in which a plurality of solar cells 200 are arranged in the horizontal direction and electrically connected to each other by a wiring 404 in series and which is enclosed by a broken line are included and the plurality of submodules 303 are electrically connected to each other in parallel or in series. Adjacent submodules are electrically connected by a busbar 405.

In adjacent solar cells 200, the n-electrode 5 on the upper side and the p-electrode 2 on the lower side are connected by the wiring 404. Both ends of the solar cell 200 in the submodule 403 are connected to the busbar 405, the busbar 405 is preferably configured to electrically connect a plurality of submodules 403 in parallel or in series and adjust the output voltage with the second solar cell module 402. Incidentally, the connection system of the solar cell 200 shown in the fourth embodiment is an example, the solar cell module can be configured by other connection systems.

### Fifth Embodiment

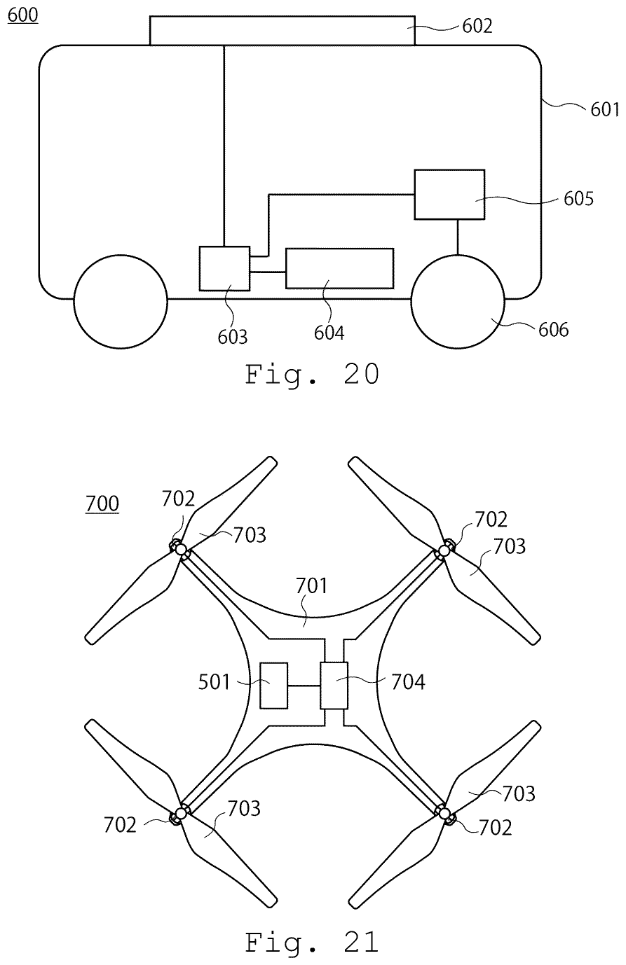

A fifth embodiment relates to a solar photovoltaic power generation system. The solar cell module according to the fourth embodiment can be used as a generator which generates electric power in the solar photovoltaic power generation system according to the fourth embodiment. The solar photovoltaic power generation system according to the embodiment generates electric power using a solar cell module and specifically includes a solar cell module which generates electric power, a unit which converts the generated electricity into electric power, and a power storage unit which stores the generated electricity or a load which consumes the generated electricity. FIG. 19 illustrates a configuration diagram of a solar photovoltaic power generation system 400 according to the embodiment. The solar photovoltaic power generation system in FIG. 19 includes a solar cell module 501 (400), a converter 502, a storage battery 503, and a load 504. Either of the storage battery 503 or the load 504 may be omitted. The load 504 may be configured to be able to utilize the electric energy stored in the storage battery 503. The converter 502 is an apparatus including a circuit or a device which performs power conversion such as voltage transformation or DC-AC conversion such as a DC-DC converter, DC-AC-converter, AC-AC-converter and the like. As the configuration of the converter 502, a suitable configuration may be adopted depending on the configuration of the generated voltage, the storage battery 503, and the load 504.

The solar cells included in the submodule 403 included the solar cell module 501 generate electric power, the electric energy is converted by the converter 502 and stored in the storage battery 503 or consumed by the load 504. It is preferable to provide the solar cell module 501 with a sunlight tracking and driving apparatus for constantly directing the solar cell module 501 toward the sun or a light collector which collects sunlight or to add an apparatus or the like for improving the power generation efficiency.

It is preferable that the solar photovoltaic power generation system 500 is used for immovable property such as dwellings, commercial facilities, and factories or for movable property such as vehicles, aircraft, and electronic devices. The electric power generation amount is expected to increase as the solar cell having an excellent conversion efficiency according to the embodiment is used in the solar cell module.

A vehicle is described as an example of utilization of the solar photovoltaic power generation system 500. FIG. 20 illustrates a conceptual configuration diagram of a vehicle 600. The vehicle 600 in FIG. 20 includes a vehicle body 601, a solar cell module 502, a power converter 603, a storage battery 604, a motor 605, and tires (wheels) 506. The electric power generated by the solar cell module 602 provided on the upper portion of the vehicle body 601 is converted by the power converter 603 and is charged in the storage battery 604 or consumed by a load such as the motor 505. The vehicle 600 can be moved by rotating the tires (wheels) 606 by the motor 505 using the electric power supplied from the solar cell module 602 or the storage battery 604. The solar cell module 602 may not be a multi-junction type but may be configured only of such as the first solar cell module including the solar cell 200 according to the second embodiment. In the case of adopting a transparent solar cell module 602, it is also preferable to use the solar cell module 502 as a window for generating electric power on the side surface of the vehicle body 501 in addition to the upper portion of the vehicle body 601.

A flying object (multi-copter) is described as an example of utilization of the solar photovoltaic power generation system 500. The flying object uses a solar cell module 300. A configuration of the flying object according to the present embodiment will be briefly described using a schematic view of a flying object 700 (quadcopter) of FIG. 21. The flying object 700 includes a solar cell module 501, a body frame 701, motors 702, rotary wings 703, and a control unit 704. The solar cell module 501, the motors 702, the rotary wings 703, and the control unit 704 are disposed in the body frame 701. The control unit 704 converts power output from the solar cell module 501 and adjusts output. The control unit 704 can further include a storage battery that stores the generated power by the solar cell module 501. The motors 702 rotate the rotary wings 703 using the power output from the solar cell module 501. By using the flying object 700 with the present configuration having the solar cell module 501 according to the embodiment, a flying object that can fly using more electric power is provided.

In the specification, some elements are represented only by chemical symbols for elements.

Hereinafter, clauses of embodiments are additionally noted.

### Clause 1

An n-type layer comprising:
amorphous gallium oxide as a main component, wherein
a conductive type of the n-type layer is n-type,
one or more lanthanoid series elements whose amount is more than 0 [atom %] and 67 [atom %] or less of Ga contained in the amorphous gallium oxide are doped at Ga (II) site of the amorphous gallium oxide.

### Clause 2

The n-type layer according to clause 1, wherein
the one or more lanthanoid series elements is at least one selected from the group consisting of Ce, La, Pr, and Nd.

### Clause 3

The n-type layer according to clause 1, wherein
the one or more lanthanoid series elements whose amount is 90 [atom %] or more and 100 [atom %] or less of Ga contained in the amorphous gallium oxide are doped at Ga (II) site of the amorphous gallium oxide.

### Clause 4

The n-type layer according to any one of clauses 1 to 3, wherein
90 [wt %] or more and 100 [wt %] or less of the n-type semiconductor layer is the amorphous gallium oxide

### Clause 5

The n-type layer according to any one of clauses 1 to 4, wherein
a total of Ga contained in the amorphous gallium oxide contained in the n-type semiconductor layer and the one or more lanthanoid series elements contained in the amorphous gallium oxide as a dopant is 95 [wt %] or more and 100 [wt %] or less of total elements excluding oxygen contained in the amorphous gallium oxide.

### Clause 6

The n-type layer according to any one of clauses 1 to 5, wherein
the one or more lanthanoid series elements doped at Ga (II) site of the amorphous gallium oxide is Ce.

### Clause 7

The n-type layer according to any one of clauses 1 to 5, wherein
the one or more lanthanoid series elements doped at Ga (II) site of the amorphous gallium oxide is La.

### Clause 8

The n-type layer according to any one of clauses 1 to 5, wherein
the one or more lanthanoid series elements doped at Ga (II) site of the amorphous gallium oxide is Pr.

### Clause 9

The n-type layer according to any one of clauses 1 to 5, wherein
the one or more lanthanoid series elements doped at Ga (II) site of the amorphous gallium oxide is Nd.

### Clause 10

The n-type layer according to any one of clause 1 to 9, wherein
the one or more lanthanoid series elements is at least one selected from the group consisting of Ce, La, Pr, and Nd,
the one or more lanthanoid series elements whose amount is 10 [atom %] or more and 40 [atom %] or less of Ga contained in the amorphous gallium oxide are doped at Ga (II) site of the amorphous gallium oxide,
the one or more lanthanoid series elements whose amount is 90 [atom %] or more and 100 [atom %] or less of Ga contained in the amorphous gallium oxide are doped at Ga (II) site of the amorphous gallium oxide,
90 [wt %] or more and 100 [wt %] or less of the n-type semiconductor layer is the amorphous gallium oxide, and
a total of Ga contained in the amorphous gallium oxide contained in the n-type semiconductor layer and the one or more lanthanoid series elements contained in the amorphous gallium oxide as a dopant is 95 [wt %] or more and 100 [wt %] or less of total elements excluding oxygen contained in the amorphous gallium oxide.

### Clause 11

A solar cell comprising:
a p-electrode;
a n-electrode;
a p-type light-absorbing layer on the p-electrode; and
an n-type layer provided between the p-type light-absorbing layer and the n-electrode and comprising the n-type semiconductor layer according to any one of clauses 1 to 10.

### Clause 12

The solar cell according to clause 11, wherein
the p-type light-absorbing layer comprises a cuprous oxide compound.

### Clause 13

A multi-junction solar cell comprising:
the solar cell according to clause 11 or 12.

### Clause 14

A solar cell module using the solar cell according to clause 11 or 12.

### Clause 15

A photovoltaic power generation system that performs photovoltaic power generation by using the solar cell module according to clause 14.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. An n-type layer comprising:
amorphous gallium oxide as a main component, wherein
a conductive type of the n-type layer is n-type, and
one or more lanthanoid series elements whose amount is more than 0 [atom %] and 67 [atom %] or less of Ga contained in the amorphous gallium oxide are doped at Ga (II) site of the amorphous gallium oxide.

2. The n-type layer according to claim 1, wherein
the one or more lanthanoid series elements is at least one selected from the group consisting of Ce, La, Pr, and Nd.

3. The n-type layer according to claim 1, wherein
the one or more lanthanoid series elements whose amount is 90 [atom %] or more and 100 [atom %] or less of Ga contained in the amorphous gallium oxide are doped at Ga (II) site of the amorphous gallium oxide.

4. The n-type layer according to claim 1, wherein
90 [wt %] or more and 100 [wt %] or less of the n-type semiconductor layer is the amorphous gallium oxide

5. The n-type layer according to claim 1, wherein
a total of Ga contained in the amorphous gallium oxide contained in the n-type semiconductor layer and the one or more lanthanoid series elements contained in the amorphous gallium oxide as a dopant is 95 [wt %] or more and 100 [wt %] or less of total elements excluding oxygen contained in the amorphous gallium oxide.

6. The n-type layer according to claim 1, wherein
the one or more lanthanoid series elements doped at Ga (II) site of the amorphous gallium oxide is Ce.

7. The n-type layer according to claim 1, wherein
the one or more lanthanoid series elements doped at Ga (II) site of the amorphous gallium oxide is La.

8. The n-type layer according to claim 1, wherein
the one or more lanthanoid series elements doped at Ga (II) site of the amorphous gallium oxide is Pr.

9. The n-type layer according to claim 1, wherein
the one or more lanthanoid series elements doped at Ga (II) site of the amorphous gallium oxide is Nd.

10. The n-type layer according to claim 1, wherein
the one or more lanthanoid series elements is at least one selected from the group consisting of Ce, La, Pr, and Nd,
the one or more lanthanoid series elements whose amount is 10 [atom %] or more and 40 [atom %] or less of Ga contained in the amorphous gallium oxide are doped at Ga (II) site of the amorphous gallium oxide,
the one or more lanthanoid series elements whose amount is 90 [atom %] or more and 100 [atom %] or less of Ga contained in the amorphous gallium oxide are doped at Ga (II) site of the amorphous gallium oxide,
90 [wt %] or more and 100 [wt %] or less of the n-type semiconductor layer is the amorphous gallium oxide, and
a total of Ga contained in the amorphous gallium oxide contained in the n-type semiconductor layer and the one or more lanthanoid series elements contained in the amorphous gallium oxide as a dopant is 95 [wt %] or more and 100 [wt %] or less of total elements excluding oxygen contained in the amorphous gallium oxide.

11. A solar cell comprising:
a p-electrode;
a n-electrode;
a p-type light-absorbing layer on the p-electrode; and
an n-type layer provided between the p-type light-absorbing layer and the n-electrode and comprising the n-type semiconductor layer according to claim 1.

12. The solar cell according to claim 11, wherein
the p-type light-absorbing layer comprises a cuprous oxide compound.

13. A multi-junction solar cell comprising:
the solar cell according to claim 11.

14. A solar cell module using the solar cell according to claim 11.

15. A photovoltaic power generation system that performs photovoltaic power generation by using the solar cell module according to claim 14.
